(19) United States
(12) Patent Application Publication
(10) Pub. No.: US 2026/0307120 A1
(43) Pub. Date: Oct. 8, 2026

(54) SUBSTRATE PROCESSING APPARATUS AND SUBSTRATE PROCESSING METHOD

(71) Applicant: Tokyo Electron Limited, Tokyo (JP)

(72) Inventors: Seunghwan LEE, Kumamoto (JP); Tomohiro YAMANOUE, Kumamoto (JP); Takeru HIROSE, Kumamoto (JP); Michitaka AMIYA, Kumamoto (JP); Tomofumi EMURA, Kumamoto (JP)

(21) Appl. No.: 19/484,092

(22) PCT Filed: May 8, 2024
(86) PCT No.: PCT/JP2024/017055

§ 371 Date: Nov. 13, 2025

(30) Foreign Application Priority Data
May 19, 2023 (JP) 2023-083328

(51) Int. Cl. B08B 15/02; G01M 3/26; H10P 70/00; H10P 72/00

(52) U.S. Cl. CPC B08B 15/02; G01M 3/26; H10P 70/80; H10P 72/0408

(57) ABSTRACT

A substrate processing device according to one aspect of the present disclosure processes a substrate using a processing fluid in a supercritical state, the substrate processing device comprising: a processing container that has a loading/unloading port for the substrate and internally forms a processing space in which the substrate is processed with the processing fluid; a lid body that opens and closes the loading/unloading port; an inner seal member that is provided between the processing container and the lid body in a state of surrounding the loading/unloading port; an outer seal member that is provided between the processing container and the lid body around the inner seal member in a state of surrounding the loading/unloading port; a movement mechanism that moves the lid body between an open position in which the loading/unloading port is opened and a closed position in which the outer seal member is in contact with the processing container and the lid body; a suction flow path for suctioning an atmosphere surrounded by the inner seal member and the outer seal member; a flow meter for detecting the flow rate of a fluid flowing through the suction flow path; a pressure sensor for detecting the pressure of the suction flow path; and a control circuit. The control circuit executes (a) a step for moving the lid body from the open position to the closed position, (b) a step for suctioning the atmosphere by means of the suction flow path after the step (a), (c) a step for calculating an integrated flow rate of the fluid flowing through the suction flow path during a period from the start of suction of the atmosphere until the pressure of the suction flow path becomes a threshold value or lower, and (d) a step for determining the state of the inner seal member on the basis of the integrated flow rate.

### TECHNICAL FIELD

The present disclosure relates to a substrate processing apparatus and a substrate processing method.

### BACKGROUND

There is known a substrate processing apparatus that performs processing on a substrate using a processing fluid in a supercritical state within a processing container (see, e.g., Patent Document 1). The processing container is provided with a loading/unloading port through which the substrate is loaded and unloaded. The loading/unloading port is sealed by a lid. A double seal mechanism is provided between an outer surface of the processing container and the lid, surrounding the loading/unloading port.

### PRIOR ART DOCUMENT

### Patent Document

Patent Document 1: Japanese U.S. Pat. No. 5,655,735

### SUMMARY OF THE INVENTION

### Problem to be Solved

The present disclosure provides a technique capable of suppressing contamination inside a processing container.

### Means to Solve the Problem

An aspect of the present disclosure relates to a substrate processing apparatus that processes a substrate using a processing fluid in a supercritical state. The substrate processing apparatus includes: a processing container having a loading/unloading port for the substrate and forming therein a processing space in which the substrate is processed with the processing fluid; a lid that opens and closes the loading/unloading port; an inner seal member provided between the processing container and the lid to surround the loading/unloading port; an outer seal member provided between the processing container and the lid to surround the loading/unloading port around the inner seal member; a moving mechanism that moves the lid between an open position where the loading/unloading port is opened and a closed position where the outer seal member is in contact with the processing container and the lid; a suction flow path that evacuates an atmosphere surrounded by the inner seal member and the outer seal member; a flow meter that detects a flow rate of a fluid flowing through the suction flow path; a pressure sensor that detects a pressure in the suction flow path; and control circuitry. The control circuitry is configured to execute: (a) a step of moving the lid from the open position to the closed position; (b) a step of evacuating the atmosphere through the suction flow path after the step (a); (c) a step of calculating an integrated flow rate of the fluid flowing through the suction flow path during a period from a start of the evacuating of the atmosphere until the pressure in the suction flow path becomes equal to or lower than a threshold; and (d) a step of determining a state of the inner seal member based on the integrated flow rate.

### Effect of the Invention

According to the present disclosure, contamination inside a processing container may be suppressed.

### BRIEF DESCRIPTION OF THE DRAWINGS

FIG. 1 is a schematic view illustrating a substrate processing apparatus according to an embodiment.

FIG. 2 is a vertical cross-sectional view illustrating an example of a processing unit.

FIG. 3 is a horizontal cross-sectional view illustrating an example of the processing unit.

FIG. 4 is a timing chart illustrating a substrate processing method according to an embodiment.

FIG. 5 is a view (1) illustrating the substrate processing method according to an embodiment.

FIG. 6 is a view (2) illustrating the substrate processing method according to an embodiment.

FIG. 7A is a view (3) illustrating the substrate processing method according to an embodiment.

FIG. 7B is a view (3) illustrating the substrate processing method according to an embodiment.

FIG. 8A is a view (4) illustrating the substrate processing method according to an embodiment.

FIG. 8B is a view (4) illustrating the substrate processing method according to an embodiment.

FIG. 9A is a view (5) illustrating the substrate processing method according to an embodiment.

FIG. 9B is a view (5) illustrating the substrate processing method according to an embodiment.

### DETAILED DESCRIPTION TO EXECUTE THE INVENTION

Hereinafter, non-limiting exemplary embodiments of the present disclosure will be described with reference to the accompanying drawings. In all of the accompanying drawings, the same or corresponding members or components will be denoted by the same or corresponding reference numerals, and redundant descriptions will be omitted. In the present specification, the X-axis direction, the Y-axis direction, and the Z-axis direction are perpendicular to each other. The X-axis direction and the Y-axis direction are horizontal directions, and the Z-axis direction is a vertical direction.

### Substrate Processing Apparatus

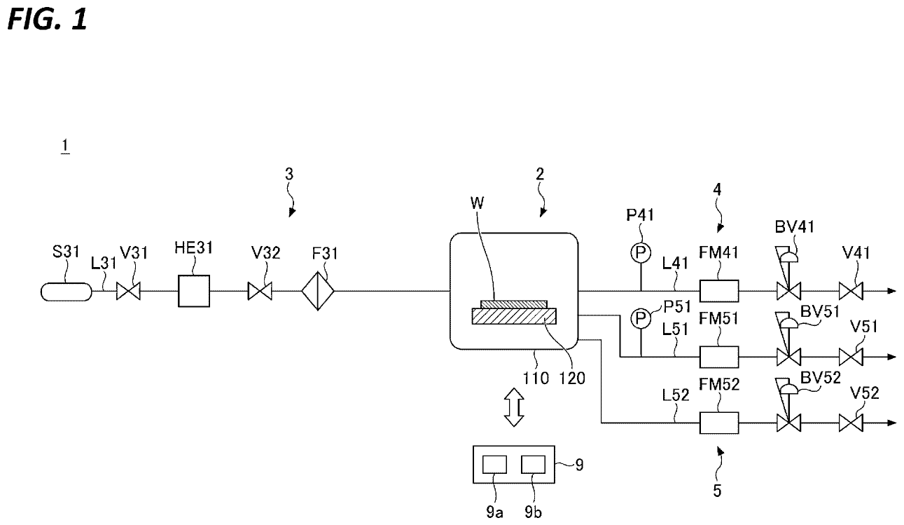

With reference to FIG. 1, a substrate processing apparatus 1 according to an embodiment will be described. FIG. 1 is a schematic view illustrating the substrate processing apparatus 1 according to an embodiment.

The substrate processing apparatus 1 is an apparatus that dries a liquid adhering to a substrate W by using a processing fluid in a supercritical state. The substrate processing apparatus 1 includes a processing unit 2, a supply unit 3, a discharge unit 4, a suction unit 5, and a control unit 9.

The processing unit 2 includes a processing container 110 and a holding unit 120. The processing container 110 is a container in which a processing space capable of accommodating a substrate W is formed. The substrate W may be, for example, a semiconductor wafer. The holding unit 120 is provided inside the processing container 110. The holding unit 120 holds the substrate W in a horizontal posture at a holding position inside the processing container 110. The processing unit 2 may further include a pressure sensor that detects the pressure inside the processing container 110 and a temperature sensor that detects the temperature inside the processing container 110. Details of the processing unit 2 will be described later.

The supply unit 3 supplies a processing fluid in a supercritical state to the processing unit 2. The supply unit 3 has a supply flow path L31.

The supply flow path L31 is connected to the processing container 110. The supply channel L31 supplies fluid into the processing container 110. A fluid source S31, an opening/closing valve V31, a heating mechanism HE31, an opening/closing valve V32, and a filter F31 are provided in the supply flow path L31 in that order from the upstream side. The supply flow path L31 may further include, for example, an orifice, an opening/closing valve, a temperature sensor, a pressure sensor, and a line heater, which are not illustrated.

The fluid source S31 includes a source of the fluid. The fluid includes, for example, a processing fluid. The processing fluid is, for example, carbon dioxide (CO₂). The fluid may further include an inert gas. The inert gas is, for example, nitrogen (N₂) gas.

The opening/closing valve V31 is a valve that switches the flow of the fluid on and off. In an open state, the opening/closing valve V31 allows the fluid to flow to the downstream heating mechanism HE31, and in a closed state, the opening/closing valve V31 prevents the fluid from flowing to the downstream heating mechanism HE31.

The heating mechanism HE31 heats the fluid to a set temperature and supplies the fluid at the set temperature to the downstream side. The heating mechanism HE31 includes, for example, a cast-in heater.

The opening/closing valve V32 is a valve that switches the flow of the fluid on and off. In an open state, the opening/closing valve V32 allows the fluid to flow to the downstream filter F31, and in a closed state, the opening/closing valve V32 prevents the fluid from flowing to the downstream filter F31.

The filter F31 filters the fluid flowing through the supply flow path L31 and removes foreign matter contained in the fluid. Thus, when performing processing on a substrate using the fluid, generation of particles on the surface of the substrate W may be suppressed.

The discharge unit 4 has a discharge flow path L41. An upstream side of the discharge flow path L41 is connected to the processing container 110. A downstream side of the discharge flow path L41 is connected to a negative pressure generating device such as an ejector or a suction pump. The discharge flow path L41 discharges the fluid from the interior of the processing container 110. A pressure sensor P41, a flow meter FM41, a back pressure valve BV41, and an opening/closing valve V41 are provided in the discharge flow path L41 in that order from the upstream side. The discharge flow path L41 may further include, for example, an opening/closing valve, a temperature sensor, a pressure sensor, and a line heater, which are not illustrated.

The pressure sensor P41 detects the pressure of the fluid flowing through the discharge flow path L41 immediately downstream of the processing container 110. Thus, the pressure inside the processing container 110 may be detected.

The flow meter FM41 detects a flow rate of the fluid flowing through the discharge flow path L41.

The back pressure valve BV41 maintains the primary-side pressure of the discharge flow path L41 at a set pressure by adjusting an opening degree of the valve to allow the fluid to flow to the secondary side when the primary-side pressure exceeds the set pressure. For example, the set pressure of the back pressure valve BV41 is adjusted by the control unit 9.

The opening/closing valve V41 is a valve that switches on and off the flow of the fluid. In an open state, the opening/closing valve V41 allows the fluid to flow to the downstream discharge flow path L41, and in a closed state, the opening/closing valve V41 prevents the fluid from flowing to the downstream discharge flow path L41.

The suction unit 5 has suction flow paths L51 and L52. However, the suction unit 5 may have the suction flow path L51 without having the suction flow path L52.

An upstream side of the suction flow path L51 is connected to the processing container 110. A downstream side of the suction flow path L51 is connected to a negative pressure generating device such as an ejector or a suction pump. The suction flow path L51 evacuates an atmosphere surrounded by an inner seal member 123 and an outer seal member 124, which will be described later. A pressure sensor P51, a flow meter FM51, a back pressure valve BV51, and an opening/closing valve V51 are provided in the suction flow path L51 in that order from the upstream side. The suction flow path L51 may further include, for example, an opening/closing valve, a temperature sensor, a pressure sensor, and a line heater, which are not illustrated.

The pressure sensor P51 detects the pressure of the fluid flowing through the suction flow path L51 immediately downstream of the processing container 110. This allows the pressure of an atmosphere surrounded by the inner seal member 123 and the outer seal member 124 to be detected.

The flow meter FM51 detects an integrated flow rate of the fluid flowing through the suction flow path L51.

The back pressure valve BV51 maintains the primary-side pressure of the suction flow path L51 at a set pressure by adjusting an opening degree of the valve to allow the fluid to flow to the secondary side when the primary-side pressure exceeds the set pressure. For example, the set pressure of the back pressure valve BV51 is adjusted by the control unit 9.

The opening/closing valve V51 is a valve that switches on and off the flow of the fluid. In an open state, the opening/closing valve V51 allows the fluid to flow to the downstream suction flow path L51, and in a closed state, the opening/closing valve V51 prevents the fluid from flowing to the downstream suction flow path L51.

An upstream side of the suction flow path L52 is connected to the processing container 110. A downstream side of the suction flow path L52 is connected to a negative pressure generating device such as an ejector or a suction pump. The suction flow path L52 evacuates an atmosphere surrounded by the inner seal member 123 and the outer seal member 124, which will be described later. A flow meter FM52, a back pressure valve BV52, and an opening/closing valve V52 are provided in the suction flow path L52 in that order from the upstream side. The suction flow path L52 may further include, for example, an opening/closing valve, a temperature sensor, a pressure sensor, and a line heater, which are not illustrated.

The flow meter FM52 detects an integrated flow rate of the fluid flowing through the suction flow path L52.

The back pressure valve BV52 maintains the primary-side pressure of the suction flow path L52 at a set pressure by adjusting an opening degree of the valve to allow the fluid to flow to the secondary side when the primary-side pressure exceeds the set pressure. For example, the set pressure of the back pressure valve BV52 is adjusted by the control unit 9.

The opening/closing valve V52 is a valve that switches on and off the flow of the fluid. In an open state, the opening/closing valve V52 allows the fluid to flow to the downstream suction flow path L52, and in a closed state, the opening/closing valve V51 prevents the fluid from flowing to the downstream suction flow path L52.

The control unit 9 receives measurement signals from various sensors and transmits control signals to various functional elements. The measurement signals include detection signals from the pressure sensors P41 and P51 and detection signals from the flow meters FM41, FM51, and FM52. The control signals include, for example, opening/closing signals for the opening/closing valves V31, V32, V41, V51, and V52, and set pressure signals for the back pressure valves BV41, BV51, and BV52.

The control unit 9 may be, for example, a computer. The control unit 9 includes a calculation unit 9a and a storage unit 9b. Programs for controlling various processes executed in the substrate processing apparatus 1 are stored in the storage unit 9b. The calculation unit 9a controls the operation of the substrate processing apparatus 1 by reading and executing a program stored in the storage unit 9b. The program may be recorded on a computer-readable storage medium and installed from the storage medium into the storage unit 9b of the control unit 9. Examples of the computer-readable storage medium include a hard disk (HD), a flexible disk (FD), a compact disk (CD), a magneto-optical disk (MO), and a memory card.

### Processing Unit

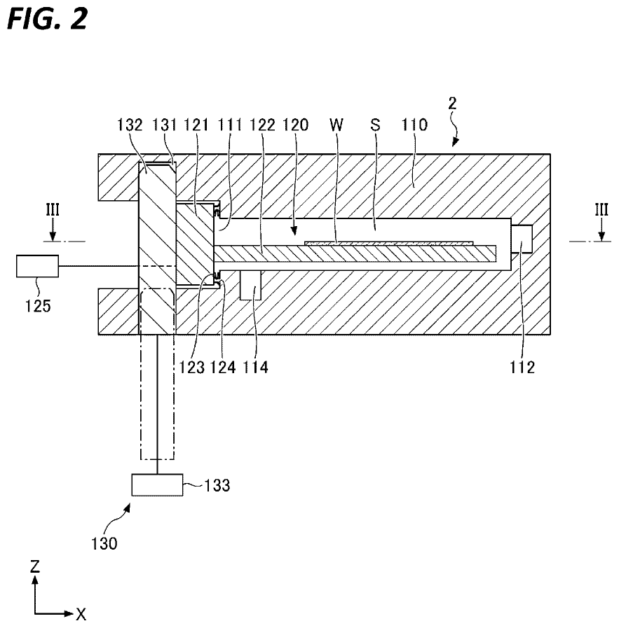

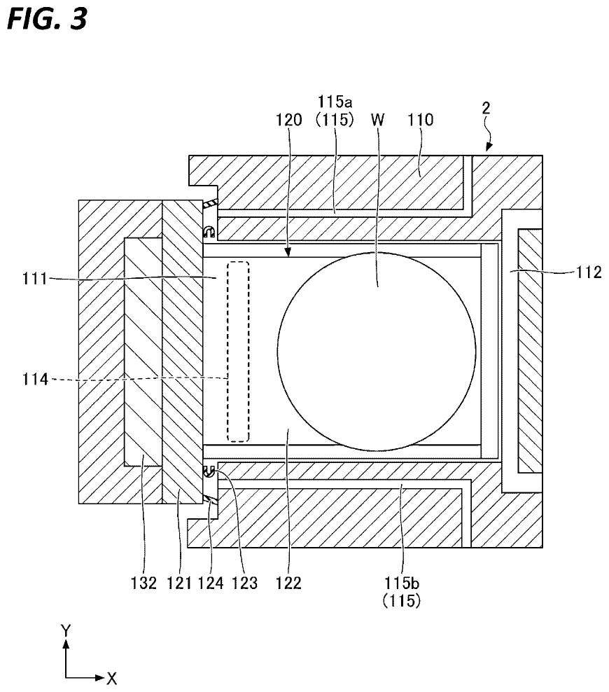

With reference to FIGS. 2 and 3, an example of the processing unit 2 will be described. FIG. 2 is a vertical cross-sectional view illustrating an example of the processing unit 2. FIG. 3 is a horizontal cross-sectional view illustrating an example of the processing unit 2, illustrating a cross section taken along line III-III in FIG. 2.

The processing unit 2 includes a processing container 110, a holding unit 120, and a lock mechanism 130.

The processing container 110 forms therein a processing space S in which a substrate W is processed with a processing fluid. The processing container 110 has a loading/unloading port 111, an ejection port 112, a discharge port 114, and a suction port 115.

The loading/unloading port 111 is provided on the negative side of the X-axis direction of the processing space S. The loading/unloading port 111 is an opening for loading and unloading a substrate W into and from the processing container 110.

The ejection port 112 ejects a fluid into the processing container 110. The ejection port 112 is provided on a side wall of the processing container 110 opposite to the loading/unloading port 111. The supply flow path L31 is connected to the ejection port 112. The ejection port 112 ejects the fluid toward the loading/unloading port 111.

The discharge port 114 discharges the fluid from the inside of the processing container 110.

The suction port 115 evacuates an atmosphere surrounded by an inner seal member 123 and an outer seal member 124, which will be described later. By providing the suction port 115 separately from the discharge port 114, the volume of the atmosphere to be evacuated may be reduced, allowing the lid 121 to be more easily brought into close contact with the processing container 110.

The suction port 115 includes suction ports 115a and 115b. The suction port 115a is provided on a side wall on the positive side in the Y-axis direction of the processing container 110. The suction flow path L51 is connected to the suction port 115a. The suction port 115b is provided on a side wall of the processing container 110 opposite to the suction port 115a. The suction port 115b is provided on a side wall on the negative side in the Y-axis direction of the processing container 110. The suction flow path L52 is connected to the suction port 115b. When the suction port 115 includes the suction ports 115a and 115b, it is easy to evenly evacuate an atmosphere surrounded by the inner seal member 123 and the outer seal member 124. However, the suction port 115 may include only the suction port 115a or only the suction port 115b.

The holding unit 120 holds a substrate W inside the processing container 110. The holding unit 120 includes a lid 121, a holding plate 122, an inner seal member 123, an outer seal member 124, and a moving mechanism 125.

The lid 121 opens and closes the loading/unloading port 111. The lid 121 has a rectangular plate shape larger than the loading/unloading port 111.

The holding plate 122 is connected to the positive side in the X-axis direction of the lid 121. The holding plate 122 extends along the horizontal direction. The holding plate 122 holds the substrate W in a horizontal posture.

The inner seal member 123 is provided on a side surface on the positive side in the X-axis direction of the lid 121. The inner seal member 123 has an annular shape and is provided in a state of surrounding the loading/unloading port 111 between the processing container 110 and the lid 121. The inner seal member 123 is, for example, a U-seal.

The outer seal member 124 is provided on a side surface on the positive side in the X-axis direction of the lid 121. The outer seal member 124 has an annular shape and is provided in a state of surrounding the loading/unloading port 111 between the processing container 110 and the lid 121 around the inner seal member 123. The outer seal member 124 is, for example, a lip seal.

The moving mechanism 125 moves the lid 121 in the horizontal direction (X-axis direction) between an open position (not illustrated) and a closed position (positions shown in FIGS. 2 and 3). The open position is a position where the loading/unloading port 111 is open. In the open position, the holding plate 122 is located outside the processing container 110, and transfer of the substrate W is performed between the holding plate 122 and a transfer arm (not illustrated). The closed position is located on the positive side in the X-axis direction relative to the open position. The closed position is a position where the loading/unloading port 111 is closed. In the closed position, the inner seal member 123 is not in contact with the processing container 110, and the outer seal member 124 is in contact with the processing container 110. In the closed position, the holding plate 122 is located inside the processing container 110.

The lock mechanism 130 restricts movement of the lid 121 in a direction away from the processing container 110. The lock mechanism 130 fixes the holding unit 120 at a processing position, which will be described later. The lock mechanism 130 includes a guide hole 131, a lock member 132, and a lifting mechanism 133. The guide hole 131 is formed in the processing container 110. The lock member 132 moves up and down along the guide hole 131. The lifting mechanism 133 moves the lock member 132 up and down between a lock position (position indicated by solid lines in FIG. 2) and an unlock position (position indicated by alternate long and short dashed lines in FIG. 2). The lock mechanism 130 fixes the holding unit 120 at the processing position, which will be described later, by moving the lock member 132 to the lock position.

### Substrate Processing Method

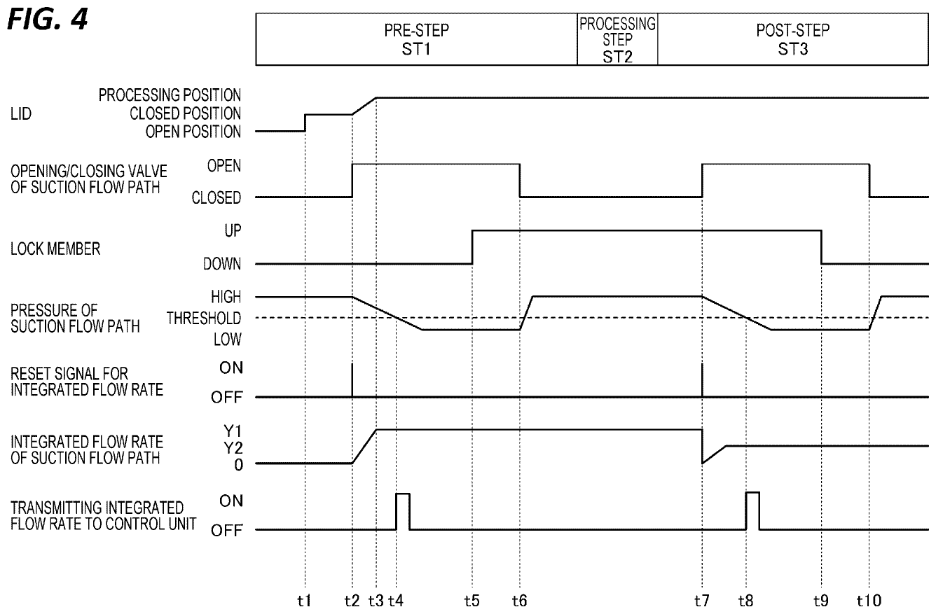

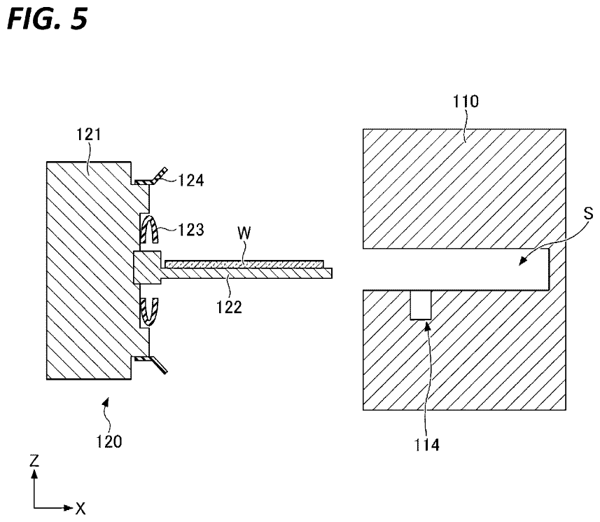

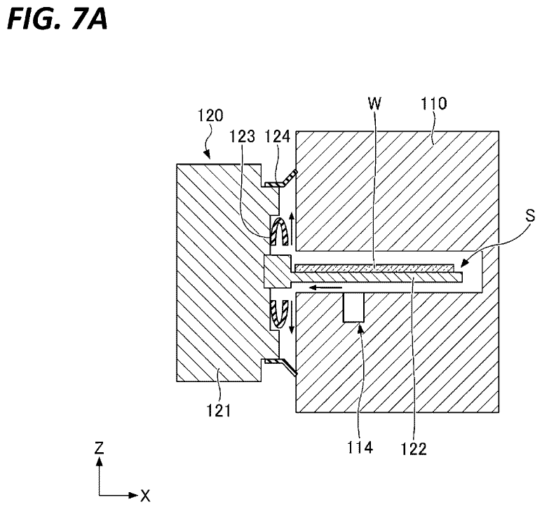

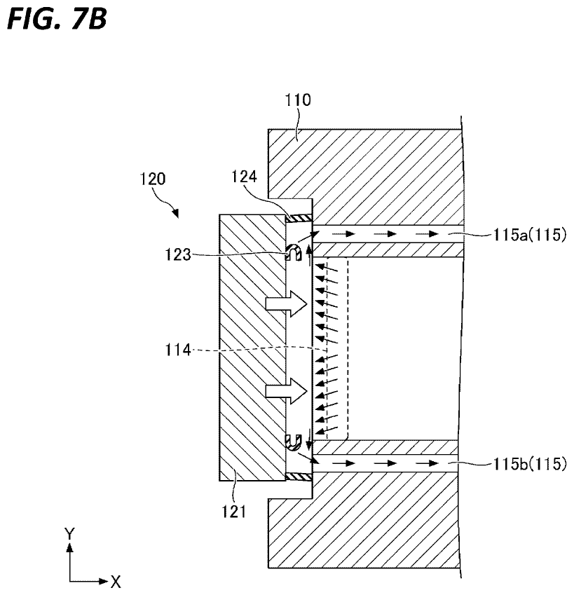

With reference to FIGS. 4, 5, 6, 7A, 7B, 8A, 8B, 9A, and 9B, a substrate processing method according to an embodiment will be described. The substrate processing method described below is automatically executed under the control of the control unit 9, based on a processing recipe and a control program stored in the storage unit 9b. FIG. 4 is a timing chart illustrating the substrate processing method according to an embodiment. FIGS. 5, 6, 7A, 7B, 8A, 8B, 9A, and 9B are views illustrating the substrate processing method according to an embodiment. FIGS. 5, 6, 7A, 8A, and 9A are vertical cross-sectional views of the processing unit 2. FIGS. 7B, 8B, and 9B are horizontal cross-sectional views of the processing unit 2.

The substrate processing method according to an embodiment is performed with the opening/closing valve V41 of the discharge unit 4 in an open state. In other words, the substrate processing method according to an embodiment is performed in a state in which the inside of the processing container 110 is evacuated through the discharge flow path L41. The substrate processing method according to an embodiment includes a pre-step ST1, a processing step ST2, and a post-step ST3.

In the pre-step ST1, first, as illustrated in FIG. 5, a substrate W is placed on the holding plate 122 of the holding unit 120, which is at the open position. For example, the substrate W has undergone a cleaning process and is in a state in which isopropyl alcohol (IPA) is filled into recesses of a surface pattern.

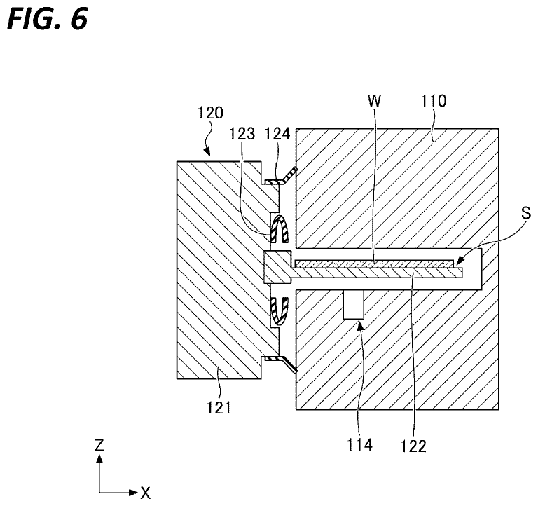

Next, at time point t1, the control unit 9 moves the holding unit 120 from the open position to the closed position. As a result, the substrate W is loaded into the processing container 110. As illustrated in FIG. 6, in the closed position, the inner seal member 123 is not in contact with the processing container 110, and the outer seal member 124 is in contact with the processing container 110.

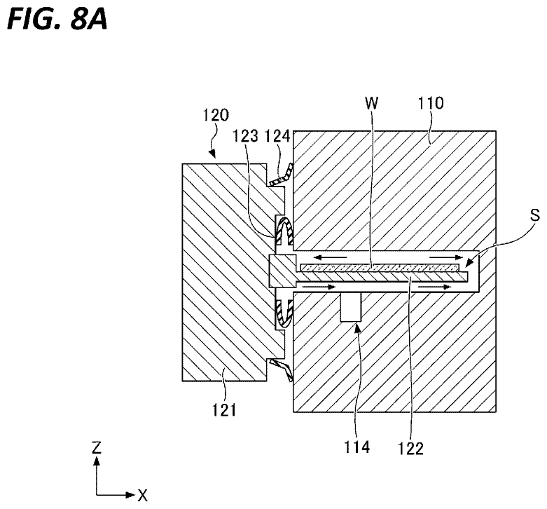

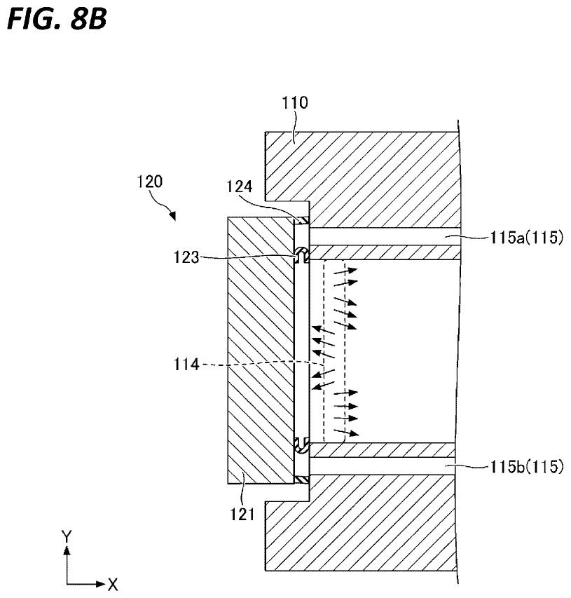

Next, at time point t2, the opening/closing valves V51 and V52 are opened. As a result, the fluid inside the processing container 110 is evacuated through the suction ports 115a and 115b and the suction flow paths L51 and L52. At this time, when the flow rate of the fluid evacuated from the suction ports 115a and 115b is greater than the flow rate of the fluid discharged from the discharge port 114, a negative pressure is generated inside the processing container 110. Therefore, as indicated by arrows in FIGS. 7A and 7B, a fluid flows occurs from the discharge port 114 toward the suction ports 115a and 115b. The fluid flow from the discharge port 114 toward the suction ports 115a and 115b occurs until time point t3 at which the holding unit 120 moves to the processing position. At the processing position, as illustrated in FIGS. 8A and 8B, the inner seal member 123 and the outer seal member 124 are in contact with the processing container 110.

At time point t2, the control unit 9 also transmits a signal to reset an integrated flow rate (hereinafter referred to as a “reset signal”) to the flow meters FM51 and FM52. As a result, the flow meters FM51 and FM52 detect an integrated flow rate from time point t2 at which the opening/closing valves V51 and V52 are opened. The integrated flow rate detected by the flow meters FM51 and FM52 increases until time point t3 at which the holding unit 120 moves to the processing position. The integrated flow rate detected by the flow meters FM51 and FM52 at time point t3 is, for example, Y1.

At time point t3, as illustrated in FIGS. 8A and 8B, in addition to the outer seal member 124, the inner seal member 123 comes into contact with the processing container 110. As a result, the lid 121 is brought into close contact with the processing container 110 via the inner seal member 123 and the outer seal member 124. At time point t3, the inner seal member 123 separates a space between the inner seal member 123 and the outer seal member 124 from the processing space S. Therefore, the fluid flow from the discharge port 114 to the suction ports 115a and 115b is cut off.

Next, at time point t4 at which the pressure detected by the pressure sensor P51 becomes equal to or lower than a threshold, the flow meters FM51 and FM52 transmit integrated flow rates to the control unit 9. As a result, an integrated flow rate detected by the flow meter FM51 during a period from time point t2 to time point t4, and an integrated flow rate detected by the flow meter FM52 during the period from time point t2 to time point t4, are transmitted to the control unit 9. The control unit 9 makes various determinations, which will be described later, based on the integrated flow rate transmitted from at least one of the flow meter FM51 and the flow meter FM52. The threshold is determined in advance by, for example, experiments.

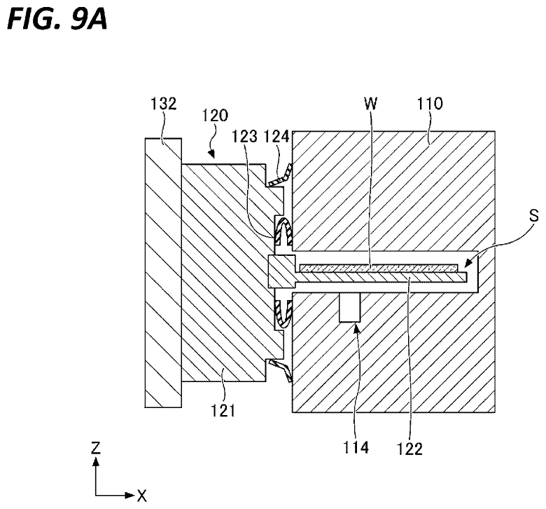

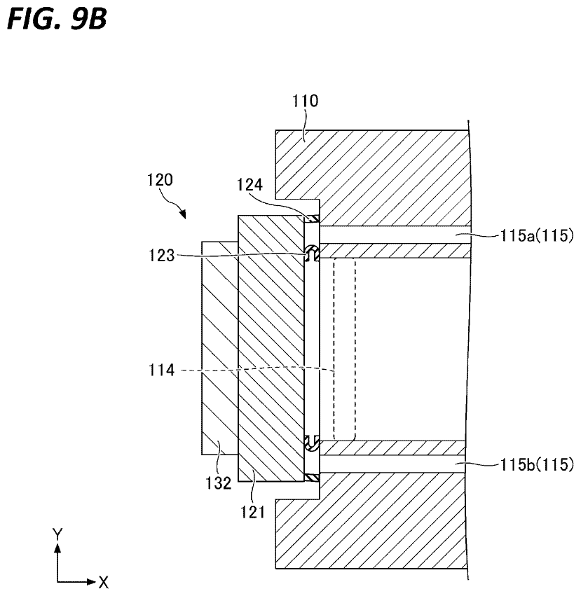

Next, at time point t5, as illustrated in FIGS. 9A and 9B, the control unit 9 moves the lock member 132 from the unlock position to the lock position. As a result, the movement of the holding unit 120 in a direction away from the processing container 110 (negative side in the X-axis direction) is restricted. A slight gap is provided between the lock member 132 at the lock position and the lid 121. In this case, the lock member 132 moves from the unlock position to the lock position without rubbing against the lid 121.

Next, at time point t6, the opening/closing valves V51 and V52 are closed. As a result, evacuation through the suction ports 115a and 115b and the suction flow paths L51 and L52 is stopped, and the pressure in the suction flow paths L51 and L52 gradually increases. As described above, the pre-step ST1 is completed.

The processing step ST2 is performed after the pre-step ST1. The processing step ST2 is initiated in a state at a time point at which the pre-step ST1 is completed. In other words, the processing step ST2 is performed in a state in which the lid 121 is at the processing position, the opening/closing valves V51 and V52 are closed, and the lock member 132 is at the lock position.

First, a pressurizing step is performed. In the pressurizing step, the opening/closing valves V31 and V32 are opened, and the opening/closing valves V41, V51, and V52 are closed. As a result, a processing fluid (CO₂) from the fluid source S31 is ejected from the ejection port 112 toward the holding plate 122 via the supply flow path L31. The CO₂ ejected from the ejection port 112 flows into the processing space S. Since the opening/closing valve V41 is closed, CO₂ does not flow out of the processing container 110. Therefore, the pressure inside the processing container 110 gradually increases. In the pressurizing step, the pressure of the processing fluid supplied into the processing container 110 is lower than a critical pressure. Therefore, the processing fluid is supplied into the processing container 110 in a gaseous state. Thereafter, as the filling of the processing fluid into the processing container 110 proceeds, the pressure inside the processing container 110 increases, and when the pressure inside the processing container 110 exceeds the critical pressure, the processing fluid present in the processing container 110 becomes a supercritical state. When the pressure inside the processing container 110 reaches a predetermined pressure higher than the critical pressure in the pressurizing step, the pressurizing step is completed and a circulating step is initiated.

The circulating step is performed after the pressurizing step. In the circulating step, the opening/closing valves V31, V32, and V41 are opened, and the opening/closing valves V51 and V52 are closed. As a result, CO₂ from the fluid source S31 is ejected into the processing container 110 from the ejection port 112 via the supply flow path L31. In the circulating step, since the pressure inside the processing container 110 is maintained at a pressure sufficiently higher than the critical pressure, there is no problem of drying even when CO₂ collides with the surface of the substrate W or flows near the surface of the substrate W. In the circulating step, supply of CO₂ into the processing container 110 and discharge of CO₂ from the processing container 110 are simultaneously performed. By performing the circulating step, replacement of IPA with CO₂ in recesses of the pattern of the substrate W is promoted. When the replacement of IPA with CO₂ in the recesses of the pattern is completed, the circulating step is completed and a depressurizing step is started.

The depressurizing step is performed after the circulating step. In the depressurizing step, the opening/closing valve V41 is opened, and the opening/closing valves V31, V32, V51, and V52 are closed. As a result, CO₂ is not supplied into the processing container 110, and CO₂ is discharged from the processing container 110. When the pressure inside the processing container 110 becomes lower than the critical pressure of CO₂ by the depressurizing step, CO₂ in a supercritical state vaporizes and leaves the recesses of the pattern. As a result, a substrate processing (drying process) for one substrate W is completed. In the processing step ST2, since the inside of the processing container 110 becomes high in pressure, a force directed toward the lock member 132 acts on the lid 121. Therefore, the lid 121 is in contact with the lock member 132.

The post-step ST3 is performed after the processing step ST2. In the post-step ST3, first, at time point t7, the opening/closing valves V51 and V52 are opened. As a result, the atmosphere surrounded by the inner seal member 123 and the outer seal member 124 is evacuated through the suction ports 115a and 115b and the suction flow paths L51 and L52. Thus, the lid 121, which is in contact with the lock member 132, is pulled toward the processing container 110 and separated from the lock member 132.

At time point t7, the control unit 9 also transmits a reset signal to the flow meters FM51 and FM52. As a result, the flow meters FM51 and FM52 are able to detect an integrated flow rate from time point t6 at which the opening/closing valves V51 and V52 are opened. The integrated flow rate detected by the flow meters FM51 and FM52 gradually increases as the atmosphere between the inner seal member 123 and the outer seal member 124 is evacuated.

Next, at time point t8 at which the pressure detected by the pressure sensor P51 becomes equal to or lower than a threshold, the flow meters FM51 and FM52 transmit integrated flow rates to the control unit 9. As a result, an integrated flow rate detected by the flow meter FM51 during a period from time point t7 to time point t8, and an integrated flow rate detected by the flow meter FM52 during the period from time point t7 to time point t8, are transmitted to the control unit 9. The control unit 9 makes various determinations, which will be described later, based on the integrated flow rate transmitted from at least one of the flow meter FM51 and the flow meter FM52. The threshold is determined in advance by, for example, experiments.

Next, at time point t9, the control unit 9 moves the lock member 132 from the lock position to the unlock position. At this time, since the atmosphere between the inner seal member 123 and the outer seal member 124 is evacuated, the lid 121 is separated from the lock member 132, so that the lock member 132 moves from the lock position to the unlock position without rubbing against the lid 121.

Next, at time point t10, the opening/closing valves V51 and V52 are closed. As a result, evacuation through the suction ports 115a and 115b and the suction flow paths L51 and L52 is stopped, and the pressure in the suction flow paths L51 and L52 gradually increases. As described above, the post-step ST3 is completed.

In the substrate processing method according to an embodiment, the control unit 9 determines a state of the inner seal member 123 based on an integrated flow rate transmitted from the flow meter FM51. For example, the control unit 9 determines that the inner seal member 123 is deteriorated when the integrated flow rate transmitted from the flow meter FM51 is equal to or greater than a predetermined value, and determines that the inner seal member 123 is normal when the integrated flow rate transmitted from the flow meter FM51 is less than the predetermined value. When the inner seal member 123 is deteriorated due to, for example, wear, a gap between the inner seal member 123 and the processing container 110 increases in a state in which the holding unit 120 is at the closed position. Therefore, when the inner seal member 123 is deteriorated, the time from the time point at which the opening/closing valves V51 and V52 are opened until the inner seal member 123 comes into contact with the processing container 110 becomes longer, and the flow rate of fluid evacuated through the suction port 115a increases. Accordingly, by comparing the integrated flow rate transmitted from the flow meter FM51 with the predetermined value, the state of the inner seal member 123 may be determined. The predetermined value is determined in advance by, for example, experiments.

The control unit 9 may determine whether to change the closed position in processing of a subsequent substrate W based on an integrated flow rate transmitted from the flow meter FM51. For example, when the integrated flow rate transmitted from the flow meter FM51 is equal to or greater than a first flow rate, the control unit 9 moves the closed position in processing of the subsequent substrate W closer to the processing container 110. In this case, the time from the time point at which the opening/closing valves V51 and V52 are opened until the inner seal member 123 comes into contact with the processing container 110 is shortened. Therefore, the time in which fluid flows from the discharge port 114 toward the processing space S is shortened, and backflow of particles from the discharge port 114 into the processing space S may be detected in advance. As a result, contamination of the processing space S may be prevented. The first flow rate is determined in advance by, for example, experiments.

The control unit 9 may determine whether to issue an alarm based on the integrated flow rate transmitted from the flow meter FM51. For example, when the integrated flow rate transmitted from the flow meter FM51 is equal to or greater than a second flow rate, the control unit 9 may issue an alarm. In this case, for example, an administrator may promptly confirm deterioration of the inner seal member 123. The alarm may include at least one of light, sound, and display. The second flow rate is determined in advance by, for example, experiments.

The control unit 9 may determine whether to stop processing in the substrate processing apparatus 1 based on an integrated flow rate transmitted from the flow meter FM51. For example, when the integrated flow rate transmitted from the flow meter FM51 is equal to or greater than a third flow rate, the control unit 9 stops processing in the substrate processing apparatus 1 after completion of processing of a current substrate W. In this case, backflow of particles from the discharge port 114 into the processing space S may be detected in advance. As a result, product defects may be prevented in advance. The third flow rate is greater than, for example, the second flow rate.

The control unit 9 may perform the various determinations described above based on an integrated flow rate transmitted from the flow meter FM52 instead of an integrated flow rate transmitted from the flow meter FM51. The control unit 9 may also perform the various determinations described above based on both the integrated flow rate transmitted from the flow meter FM51 and the integrated flow rate transmitted from the flow meter FM52. For example, the control unit 9 may perform the various determinations described above based on a calculated value obtained from the integrated flow rate transmitted from the flow meter FM51 and the integrated flow rate transmitted from the flow meter FM52. The calculated value is, for example, an average value. For example, the control unit 9 may compare the integrated flow rate transmitted from the flow meter FM51 with the integrated flow rate transmitted from the flow meter FM52, and perform the various determinations described above based on the larger integrated flow rate of the two.

The embodiments disclosed herein are to be considered illustrative in all respects and not restrictive. The above embodiments may be omitted, substituted, or modified in various forms without departing from the scope and spirit of the appended claims.

In the present disclosure, the control unit 9 is electronic circuitry such as a central processing unit (CPU), a field programmable gate array (FPGA), or an application specific integrated circuit (ASIC), and executes various control operations described in this specification by executing instruction codes stored in memory or by being circuit-designed for a specific application.

The present international application claims priority based on Japanese Patent Application No. 2023-083328 filed on May 19, 2023, the entire contents of which are incorporated herein by reference.

### DESCRIPTION OF SYMBOLS

1: substrate processing apparatus
9: control unit
110: processing container
111: loading/unloading port
121: lid
123: inner seal member
124: outer sealing member
125: moving mechanism
L51, L52: suction flow path
FM51, FM52: flow meter
P51: pressure sensor
S: processing space
W: substrate

1. A substrate processing apparatus comprising:
a processing container having a loading/unloading port for a substrate and forming therein a processing space in which the substrate is processed with a processing fluid in a supercritical state;
a lid configured to open and close the loading/unloading port;
an inner seal provided between the processing container and the lid to surround the loading/unloading port;
an outer seal provided between the processing container and the lid to surround the loading/unloading port around the inner seal;
a drive configured to move the lid between an open position where the loading/unloading port is opened and a closed position where the outer seal is in contact with the processing container and the lid;
a suction flow path configured to evacuate an atmosphere surrounded by the inner seal and the outer seal;
a flow meter configured to detect a flow rate of a fluid flowing through the suction flow path;
a pressure sensor configured to detect a pressure in the suction flow path; and
control circuitry,
wherein the control circuitry is configured to execute:
(a) moving the lid from the open position to the closed position;
(b) evacuating the atmosphere through the suction flow path after (a);
(c) calculating an integrated flow rate of the fluid flowing through the suction flow path during a period from a start of the evacuating of the atmosphere until the pressure in the suction flow path becomes equal to or lower than a threshold; and
(d) determining a state of the inner seal based on the integrated flow rate.

2. The substrate processing apparatus of claim 1, wherein when the integrated flow rate is equal to or greater than a first flow rate, the control circuitry is configured to move the closed position in processing of a subsequent substrate closer to the processing container.

3. The substrate processing apparatus of claim 1, wherein when the integrated flow rate is equal to or greater than a second flow rate, the control circuitry is configured to issue an alarm.

4. The substrate processing apparatus of claim 1, wherein when the integrated flow rate is equal to or greater than a third flow rate, the control circuitry is configured to stop processing in the substrate processing apparatus after completion of processing of a current substrate.

5. The substrate processing apparatus according to claim 1, further comprising:
a discharge flow path configured to discharge the fluid from the processing space,
wherein (b) includes discharging the fluid from the processing space through the discharge flow path.

6. The substrate processing apparatus according to claim 1, further comprising:
a lock configured to restrict movement of the lid in a direction away from the processing container,
wherein the control circuitry is further configured to execute:
(e) moving the lock from an unlock position where movement of the lid is not restricted to a lock position where movement of the lid is restricted after (b); and
(f) of stopping the evacuating of the atmosphere through the suction flow path after (e).

7. The substrate processing apparatus of claim 6, wherein the control circuitry is further configured to execute:
(g) supplying the processing fluid into the processing space and performing processing on the substrate after (f);
(h) of evacuating the atmosphere through the suction flow path after (g);
(i) calculating an integrated flow rate of the fluid flowing through the suction flow path during a period from a start of the evacuating of the atmosphere until a pressure in the suction flow path becomes equal to or lower than a threshold in (h); and
(j) moving the lock member from the lock position to the unlock position after the step (h).

8. The substrate processing apparatus according to claim 1, wherein the inner seal is a U-seal.

9. The substrate processing apparatus according to claim 1, wherein the outer seal is a lip seal.

10. A substrate processing method comprising:
providing a substrate processing apparatus including:
a processing container having a loading/unloading port for a substrate and forming therein a processing space in which the substrate is processed with a processing fluid in a supercritical state;
a lid configured to open and close the loading/unloading port;
an inner seal provided between the processing container and the lid to surround the loading/unloading port;
an outer seal provided between the processing container and the lid to surround the loading/unloading port around the inner seal
a drive configured to move the lid between an open position where the loading/unloading port is opened and a closed position where the outer seal is in contact with the processing container and the lid;
a suction flow path configured to evacuate an atmosphere surrounded by the inner seal and the outer seal
a flow meter configured to detect a flow rate of a fluid flowing through the suction flow path;
a pressure sensor configured to detect a pressure in the suction flow path;
moving the lid from the open position to the closed position;
evacuating the atmosphere through the suction flow path after the moving;
calculating an integrated flow rate of the fluid flowing through the suction flow path during a period from a start of the evacuating of the atmosphere until the pressure in the suction flow path becomes equal to or lower than a threshold; and
determining a state of the inner seal based on the integrated flow rate.
